(19) United States
(12) Patent Application Publication
(10) Pub. No.: US 2025/0056992 A1
(43) Pub. Date: Feb. 13, 2025

(54) ARRAY BASE PLATE, DISPLAY MODULE, AND DISPLAY APPARATUS

(71) Applicants: Hefei Visionox Technology Co., Ltd., Hefei (CN); KunShan Go-Visionox Opto-Electronics Co., Ltd, Kunshan (CN)

(72) Inventors: Xi ZHU, Hefei (CN); Dawei SUN, Hefei (CN); Lu ZHANG, Hefei (CN)

(73) Assignees: Hefei Visionox Technology Co., Ltd., Hefei (CN); KunShan Go-Visionox Opto-Electronics Co., Ltd, Kunshan (CN)

(21) Appl. No.: 18/921,474

(22) Filed: Oct. 21, 2024

(30) Foreign Application Priority Data
Nov. 9, 2023 (CN) 202311507099.X

(51) Int. Cl. H10K 59/131

(52) U.S. Cl. CPC H10K 59/131

(57) ABSTRACT

An array base plate, a display module, and a display apparatus. The array base plate includes: a plurality of pixel circuit groups each including a plurality of pixel circuits, the pixel circuits of the plurality of pixel circuit groups being distributed in an array; a drive circuit; a plurality of line groups, the drive circuit being connected with the pixel circuit groups through the line groups, each of the line groups including n first signal lines, the n first signal lines in the line group being configured to transmit a synchronization signal, and n being a positive integer greater than one; and a connecting line configured to connect at least two first signal lines in a same line group.

### CROSS REFERENCE TO RELATED APPLICATION

The present application claims priority to Chinese Patent Application No. 202311507099.X filed on Nov. 9, 2023, which is incorporated herein by reference in its entirety.

### TECHNICAL FIELD

The present application relates to the technical field of display device, and particularly to an array base plate, a display module, and a display apparatus.

### BACKGROUND

Planar display apparatus based on Organic Light Emitting Diode (OLED) and Light Emitting Diode (LED), etc., are widely used in cell phones, TVs, notebook computers, desktop computers and other consumer electronic products due to their high image quality, power saving, thin body and wide range of applications, and have become the mainstream of the display apparatus.

However, the using performance of the current OLED display products needs to be improved.

### SUMMARY

Embodiments of the present application provide an array base plate, a display module, and a display apparatus, aiming to improve the using performance of the display panel.

Some embodiments of a first aspect of the present application provide an array base plate, including: a plurality of pixel circuit groups each including a plurality of pixel circuits, the pixel circuits of the plurality of pixel circuit groups being distributed in an array; a drive circuit; a plurality of line groups, the drive circuit being connected with the pixel circuit groups through the line groups, each of the line groups including n first signal lines, the n first signal lines in the line group being configured to transmit a synchronization signal, and n being a positive integer greater than one; and at least one connecting line configured to connect at least two first signal lines in a same line group.

Some embodiments of a second aspect of the present application further provide a display panel including the array base plate according to any above embodiment of the first aspect.

Some embodiments of a third aspect of the present application further provide a display module including the display panel of the second aspect or the array base plate according to any above embodiment of the first aspect.

Some embodiments of a fourth aspect of the present application further provide a display apparatus including the above display module.

The array base plate according to the embodiments of the present application includes a plurality of pixel circuit groups, a drive circuit, and a plurality of line groups, the pixel circuit group includes a plurality of pixel circuits, and the drive circuit is connected with the pixel circuits in the corresponding pixel circuit group through the line group, so that the drive circuit can send drive signals to the pixel circuits. A same line group includes n first signal lines for connecting the drive circuit with a same pixel circuit group. At least two of the first signal lines in the line group are connected to each other by a connecting line, so that the two first signal lines can be mutually connected to send a same drive signal, which can improve the stability of signal transmission between the drive circuit and the pixel circuits. When the array base plate is used in a display panel, the display effect of the display panel can be improved, and the using performance of the display panel is increased.

### BRIEF DESCRIPTION OF THE DRAWINGS

Other features, objects, and advantages of the present application will be more apparent from reading the following detailed description of non-limiting embodiments with reference to the accompanying drawings, in which the same or similar reference numerals denote the same or similar features.

FIG. 1 shows a schematic structural diagram of an array base plate according to an embodiment of the present application;

FIG. 2 shows a partially enlarged schematic structural diagram at P in FIG. 1;

FIG. 3 shows a partially enlarged schematic structural diagram at Q in FIG. 1;

FIG. 4 shows a pixel circuit diagram of an array base plate according to an embodiment of the present application;

FIG. 5 shows a simplified circuit diagram of an array base plate according to an embodiment of the present application;

FIG. 6 shows a schematic structural diagram of local wiring of an array base plate according to an embodiment of the present application;

FIG. 7 shows a partially enlarged schematic structural diagram at Q in FIG. 1 of another embodiment of the present application;

FIG. 8 shows a simplified circuit diagram of an array base plate according to another embodiment of the present application;

FIG. 9 shows a schematic structural diagram of local wiring of an array base plate according to another embodiment of the present application;

FIG. 10 shows a partially enlarged schematic structural diagram at Q in FIG. 1 of yet another embodiment of the present application;

FIG. 11 shows a simplified circuit diagram of an array base plate according to yet another embodiment of the present application;

FIG. 12 shows a schematic structural diagram of local wiring of an array base plate according to yet another embodiment of the present application;

FIG. 13 shows a partial sectional view of an array base plate according to an embodiment of the present application;

FIG. 14 shows another partial sectional view of an array base plate according to an embodiment of the present application.

### REFERENCE NUMERALS

10, array base plate; 11, pixel circuit group; 12, drive circuit; 13, line group;
100, pixel circuit; 110, drive module; 120, second initialization module; 130, first initialization module; 140, light-emitting module; 150, data writing module; 160, compensation module; 170, storage module; 181, first light emitting control module; 182, second light emitting control module; 190, third initialization module;
200, first signal line; 210, sub-segment;
300, connecting line; 310, first connecting line; 320, second connecting line;
400, linking line;
HA, first area; AA, second area; NA, non-display area.

### DETAILED DESCRIPTION

In the description of the present application, it should be noted that, unless otherwise indicated, term “a plurality of” means two or more; the orientation or positional relationships indicated by terms “up”, “down”, “left”, “right”, “inside”, “outside”, and the like are only for facilitating the description of the present application and simplifying the description, but not for indicating or implying that the device or element referred to must have a particular orientation, be constructed and operated in a particular orientation, and thus should not be construed as limiting the present application. Furthermore, terms “first”, “second”, and the like are used only for description, and should not to be construed as indicating or implying relative importance.

In the description of the present application, it should be further noted that, unless otherwise expressly specified and defined, terms “mount” and “connect” should be understood in a broad sense, e.g., a fixed connection, a removable connection, or an integrated connection; a direct connection, or an indirect connection.

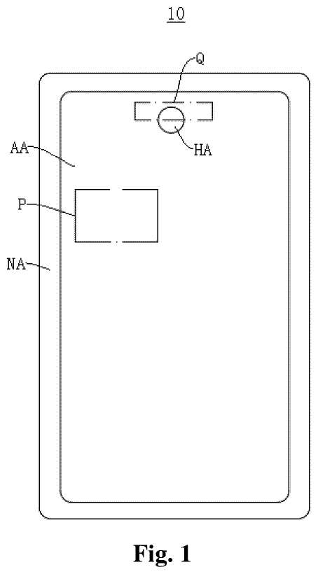

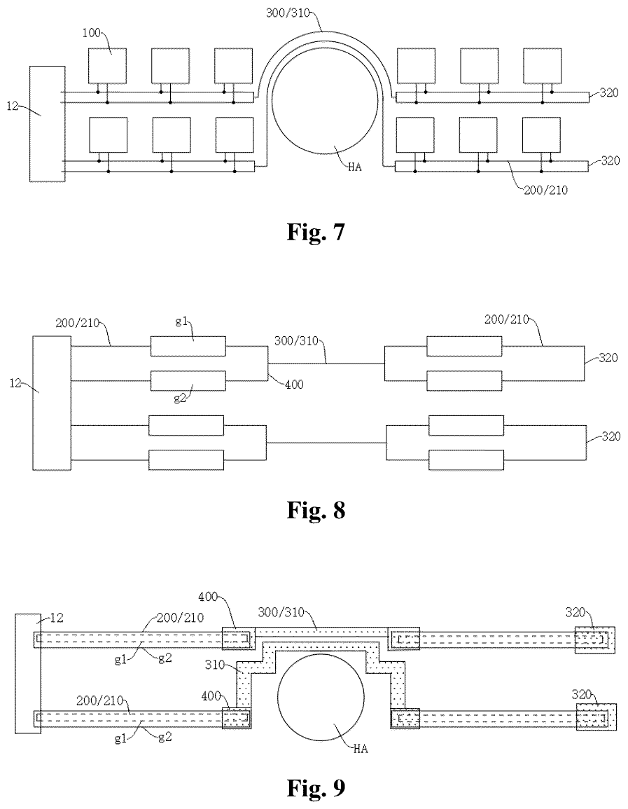

For a better understanding of the present application, the array base plate, the display panel, and the display apparatus according to the embodiments of the present application are described in detail below in connection with FIGS. 1 to 14.

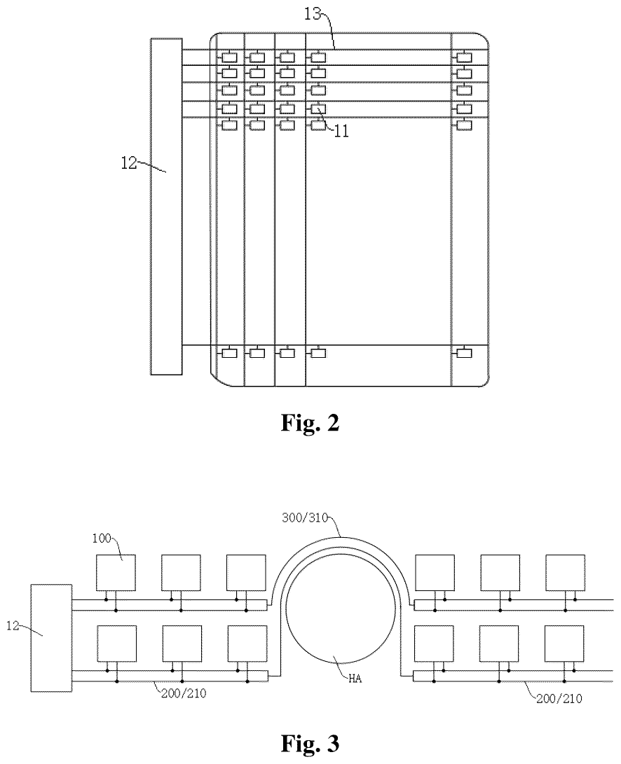

Reference is made to FIGS. 1-3, in which FIG. 1 shows a schematic structural diagram of an array base plate according to an embodiment of the present application, FIG. 2 shows a partially enlarged schematic structural diagram at P in FIG. 1, and FIG. 3 shows a partially enlarged schematic structural diagram at Q in FIG. 1.

Referring to FIGS. 1-3, the embodiments of the first aspect of the present application provide an array base plate 10 including a plurality of pixel circuit groups 11, a drive circuit 12, a plurality of line groups 13, and at least one connecting line 300. The pixel circuit group 11 includes a plurality of pixel circuits 100, the pixel circuits 100 of the plurality of pixel circuit groups 11 are distributed in an array; the drive circuit 12 is connected with the pixel circuit groups 11 through the line groups 13, each of the line groups 13 includes n first signal lines 200, the n first signal lines 200 in the line group 13 are configured to transmit a synchronization signal, and n is a positive integer greater than one; the at least one connecting line 300 is configured to connect at least two first signal lines 200 in a same line group 13.

The array base plate 10 according to the embodiments of the present application includes a plurality of pixel circuit groups 11, a drive circuit 12, and a plurality of line groups 13, the pixel circuit group 11 includes a plurality of pixel circuits 100, and the drive circuit 12 is connected with the pixel circuits 100 in the corresponding pixel circuit group 11 through the line group 13, so that the drive circuit 12 can send drive signals to the pixel circuits 100. A same line group 13 includes n first signal lines 200 for connecting the drive circuit with a same pixel circuit group 11. At least two of the first signal lines 200 in the line group 13 are connected to each other by a connecting line 300, so that the two first signal lines 200 can be mutually connected to send a same drive signal, which can improve the stability of signal transmission between the drive circuit 12 and the pixel circuits 100. When the array base plate 10 is used in a display panel, the display effect of the display panel can be improved, and the using performance of the display panel is increased.

The pixel circuit group 11 may be arranged in various ways and may include one or more rows of the pixel circuits 100. The first signal lines 200 in the line group 13 may be connected to a same row of the pixel circuits 100 in the pixel circuit group 11. The first signal line 200 may be, for example, a scanning signal line, and the drive circuit 12 is a scanning drive circuit, such as a GIP circuit. The scanning drive circuit is connected with a corresponding row of the pixel circuits 100 through the first signal lines 200. In other implementations, the pixel circuit group 11 may include one or more columns of pixel circuits 100.

Optionally, the number of rows of the pixel circuits 100 included in the pixel circuit group 11 is less than the number of the first signal lines 200 in the line group 13, so that two or more first signal lines 200 may be connected to the pixel circuits 100 in a same row, which can improve signal transmission between the drive circuit 12 and the pixel circuits 100.

Optionally, the line groups 13 and the pixel circuit groups 11 are in one-to-one correspondence, i.e., a same pixel circuit group 11 is connected with the drive circuit 12 through the n first signal lines 200 in a same line group 13.

In some optional embodiments, the pixel circuit group 11 includes at least one row of the pixel circuits 100, so that the pixel circuits 100 of the at least one row are connected with the drive circuit 12 through the n first signal lines 200 in a same line group 13 to improve signal transmission between the drive circuit 12 and the pixel circuits 100.

In some optional embodiments, as shown in FIG. 3, the pixel circuit group 11 includes two rows of the pixel circuits 100, n is equal to four, and the pixel circuits 100 in a same row are connected with two first signal lines 200.

In these optional embodiments, the plurality of pixel circuits 100 in a same row are connected with the drive circuit 12 through two first signal lines 200, which can improve signal transmission between the drive circuit 12 and the pixel circuits 100.

Optionally, the plurality of pixel circuits 100 within the pixel circuit group 11 are located in two adjacent rows, i.e., the pixel circuit group 11 includes two adjacent rows of the pixel circuits 100. The two rows of the pixel circuits 100 within a same pixel circuit group 11 are adjacent, which can reduce the distance between the plurality of pixel circuits 100 within the pixel circuit group 11 and facilitate the arrangement of the plurality of first signal lines 200.

In some optional embodiments, the pixel circuit 100 includes a plurality of functional modules, and the two first signal lines 200 connected to the pixel circuits 100 in a same row are connected to different functional modules, so that the two first signal lines 200 can transmit signals to different functional modules.

Alternatively, in other embodiments, at least one of the plurality of functional modules includes two control terminals, and the two first signal lines 200 connected to the pixel circuits 100 in a same row are connected with the two control terminals of a same functional module, so that the two first signal lines 200 can transmit a synchronization signal to a same functional module, which can improve the stability of signal transmission.

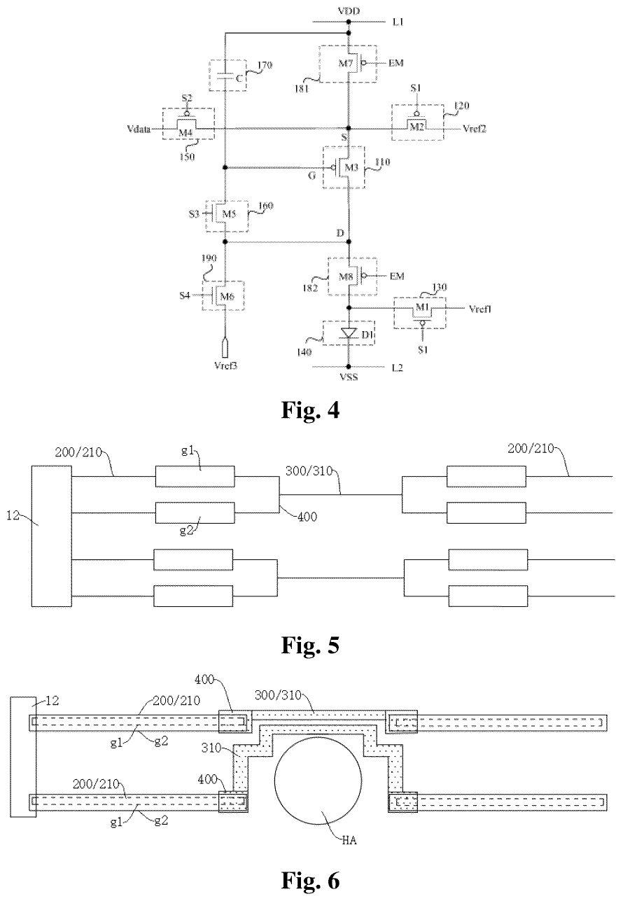

Optionally, as shown in FIG. 4, the functional modules include a compensation module 160, the compensation module 160 includes a compensation transistor M5 with two gates, and the two gates form the two control terminals. In these optional embodiments, the two gates form the two control terminals, therefore the two first signal lines 200 may be connected correspondingly with the two gates of a same compensation transistor M5.

Optionally, the two gates are a top gate and a bottom gate, respectively. For example, the compensation transistor M5 includes a semiconductor portion, the array base plate 10 further includes a substrate, the pixel circuit 100 is arranged on the substrate, the compensation transistor M5 includes two gates, one of the gates is located at a side of the semiconductor portion towards the substrate and forms the bottom gate, and the other of the gates is located at a side of the semiconductor portion away from the substrate and forms the top gate, so that the two gates can control the turning on and off of a same semiconductor portion. The compensation transistor M5 may be an oxide transistor, i.e., the active layer of the compensation transistor M5 is an oxide, such as indium gallium zinc oxide (IGZO).

Optionally, if the pixel circuit group 11 includes two rows of the pixel circuits 100 and the line group 13 includes four first signal lines 200, two of the first signal lines 200 may be connected to the top gates and the bottom gates of the compensation transistors of the pixel circuits 100 in one row, and the other two of the first signal lines 200 may be connected to the top gates and the bottom gates of the compensation transistors of the pixel circuits 100 in the other row. The compensation transistors of the two rows of the pixel circuits 100 are arranged correspondingly with four first signal lines 200.

Optionally, as shown in FIG. 4, the pixel circuit 100 includes a drive module 110, a first initialization module 130, a second initialization module 120, a third initialization module 190, a light emitting control module, a data writing module 150, a compensation module 160, and a storage module 170. The light emitting control module includes a first light emitting control module 181 and a second light emitting control module 182.

Optionally, the first initialization module 130 includes a first transistor M1, the gate of the first transistor M1 is connected with a first scan line S1, a first terminal of the first transistor M1 is connected with a first initialization signal line Vref1, and a second terminal of the first transistor M1 is connected with a first end of a light-emitting module 140. The first transistor M1 is configured to transmit, in a first initialization phase, a first initialization voltage on the first initialization signal line to the first end of the light-emitting module 140.

Optionally, the second initialization module 120 includes a second transistor M2, the gate of the second transistor M2 is connected with the first scan line S1, a first terminal of the second transistor M2 is connected with a second initialization signal line Vref2, and a second terminal of the second transistor M2 is connected with a first end S or a second end D of the drive module 110. The second transistor M2 is configured to transmit, in a second initialization phase, a second initialization voltage on the second initialization signal line Vref2 to the first end S or the second end D of the drive module 110.

Optionally, the drive module 110 includes a third transistor M3, the data writing module 150 includes a fourth transistor M4, the compensation module 160 includes a fifth transistor M5, the third initialization module 190 includes a sixth transistor M6, the first light emitting control module 181 includes a seventh transistor M7, the second light emitting control module 182 includes an eighth transistor M8, the light-emitting module 140 includes a light-emitting diode D1, and the storage module 170 includes a capacitor C.

The gate of the fourth transistor M4 is connected with a second scan line S2, a first terminal of the fourth transistor M4 is connected with a data line, and a second terminal of the fourth transistor M4 is connected with a first terminal of the third transistor M3; the gate of the fifth transistor M5 is connected with a third scan line S3, a first terminal of the fifth transistor M5 is connected with a second terminal of the third transistor M3, and a second terminal of the fifth transistor M5 is connected with the gate of the third transistor M3; the gate of the sixth transistor M6 is connected with a fourth scan line S4, a first terminal of the sixth transistor M6 is connected with the second initialization signal line Vref2, and a second terminal of the sixth transistor M6 is connected with the first terminal of the fifth transistor M5; the gate of the seventh transistor M7 and the gate of the eighth transistor M8 are both connected with a light emitting control signal line EM, a first terminal of the seventh transistor M7 is connected with a first power line L1, a second terminal of the seventh transistor M7 is connected with the first terminal of the third transistor M3, a first terminal of the eighth transistor M8 is connected with the second terminal of the third transistor M3, a second terminal of the eighth transistor M8 is connected with a first terminal of the light-emitting diode D1, and a second terminal of the light-emitting diode D1 is connected with a second power line L2; a first terminal of the capacitor C is connected with the first power line L1, and a second terminal of the capacitor C is connected with the gate of the third transistor M3.

In the above embodiments, the first terminal of the light-emitting diode D1 may be an anode, and the second terminal of the light-emitting diode D1 may be a cathode. The fifth transistor M5 and the sixth transistor M6 may be N-type transistors or P-type transistors, and all the other transistors are P-type transistors. FIG. 4 only shows the case in which the fifth transistor M5 and the sixth transistor M6 are N-type transistors, for example, both the fifth transistor M5 and the sixth transistor M6 may be metal oxide transistors, which can reduce the gate leakage of the third transistor M3 and facilitate maintaining the stability of the gate voltage of the third transistor M3.

Optionally, the first signal line 200 may be the above third scan line S3. Optionally, as described above, the fifth transistor M5 of the compensation module 160 may include a top gate and a bottom gate each connected with a first signal line 200 (i.e., the third scan line S3).

Reference is made to FIGS. 1-6, in which FIG. 5 shows a simplified circuit diagram of an array base plate 10 according to an embodiment of the present application, and FIG. 6 shows a schematic structural diagram of local wiring of an array base plate 10 according to an embodiment of the present application.

In some optional embodiments, the array base plate 10 further includes at least one connecting line 300 configured to connect at least two first signal lines 200 in a same line group 13. If the number of connecting lines 300 is two or more, at least one of the connecting lines 300 is configured to connect at least two first signal lines 200 in a same line group 13. FIG. 5 illustrates only the connection relationship between the first signal line 200, the connecting line 300, and the drive circuit 12, and FIG. 6 illustrates a partial layout of the first signal line 200, the connecting line 300, and the drive circuit 12. In FIG. 6, the two first signal lines 200 connected to the pixel circuits 100 in a same row are located in different layers and overlap, one of the first signal lines 200 is illustrated by a solid line, and the other of the first signal lines 200 is illustrated by a dashed line.

In these embodiments, at least two first signal lines 200 in the line group 13 are connected to each other by the connecting line 300, so that the two first signal lines 200 can be mutually connected. In addition, by setting the number of connecting lines 300 corresponding to a same line group 13 to be less than n, the number of wires at the location of the connecting lines 300 can be reduced, and the width of the wiring area at the location of the connecting lines 300 is reduced.

Optionally, the connecting line 300 may be directly connected to the first signal line 200, or as described above, if the first signal line 200 is connected with the gate of the compensation transistor M5, the connecting line 300 may be connected to the gate of the compensation transistor M5 and connected with the first signal line 200 through the gate of the compensation transistor M5. Therefore, at least two of the four gates of the compensation transistors M5 of the two compensation modules 160 of the two rows of the pixel circuits 100 are connected to each other through the connecting line 300. Optionally, two gates of a same compensation transistor M5 may be connected to each other, so as to simplify the wiring of the array base plate 10. Optionally, the gate may be reused as a portion of the first signal line 200, as described above.

In some optional embodiments, the plurality of line groups 13 include at least a first line group, and each first signal line 200 in the first line group includes two sub-segments 210 spaced apart; the at least one connecting line 300 includes at least one first connecting line 310, the first connecting line 310 connects the sub-segments 210 of n first signal lines in a same first line group, and the number of first connecting lines 310 corresponding to the first line group is greater than 1 and less than or equal to (n-1).

In these optional embodiments, the plurality of line groups 13 include at least a first line group, i.e., at least one of the plurality of line groups 13 is the first line group, each first signal line 200 in the first line group includes two sub-segments 210 spaced apart, and the two sub-segments 210 of a same first signal line 200 are configured to connect a plurality of pixel circuits 100 in a same row. The at least one connecting line 300 includes at least one first connecting line 310, the first connecting line 310 connects the sub-segments 210 of n first signal lines in a same first line group, and the number of first connecting lines 310 is less than the number of the first signal lines 200 in the corresponding first line group. For example, four sub-segments 210 of two first signal lines 200 are connected to each other through one first connecting line 310, or eight sub-segments 210 of four first signal lines 200 are connected to each other through two or three first connecting lines 310, so that the number of the first connecting lines 310 is less than the number of the first signal lines 200 in the corresponding first line group, which can reduce the number of the first connecting lines 310 and reduce the width of the wiring area at the location of the first connecting lines 310.

In some optional embodiments, the array base plate 10 includes at least a first area HA. Optionally, the first area HA may be a hole area of the display panel and configured to arrange an under-screen component such as a camera. The array base plate 10 further includes a second area AA arranged around at least a portion of the first area HA and may be a normal display area, the first signal lines 200 may be located in the second area AA, and the at least a portion of the first signal lines 200 within the second area AA may be separated by the first area HA into two sub-segments 210, i.e., the two sub-segments 210 of a same first signal line 200 are arranged at two sides of the first area HA, respectively.

Optionally, the first connecting line 310 may connect the sub-segments 210 located at two sides of the first area HA, for example, at least one first connecting line 310 is around at least a portion of the first area HA and connects the sub-segments 210 of at least two first signal lines 200 in a same first line group. A same first connecting line 310 may connect four sub-segments 210 of two first signal lines 200, which can reduce the number of the first connecting lines 310 and reduce the width of the wiring area outside the first area HA. The present application can reduce the load on the drive circuit, decrease drive hysteresis, and further reduce the uneven display at two sides of the first area HA under low gray-scale images.

Additionally, by arranging a same first connecting line 310 to connect the sub-segments 210 of two first signal lines 200, drive hysteresis can be decreased, and the uneven display at two sides of the first area HA under low gray-scale images is reduced.

Optionally, the at least one first connecting line 310 includes a plurality of first connecting lines 310, at least two of the plurality of first connecting lines 310 may be arranged in different layers, so as to further reduce the size of the wiring area around the first area HA. In other embodiments, at least two of the plurality of first connecting lines 310 may be arranged in a same layer to simplify the preparation process.

Position of the film layers of the first connecting line 310 may be arranged in various ways. For example, the array base plate 10 includes a substrate, and the first connecting line 310 may be arranged at a side of the first signal line 200 away from or close to the substrate.

Optionally, as described above, n may be equal to four, the pixel circuit group 11 includes two rows of the pixel circuits 100, the pixel circuits 100 in a same row are connected correspondingly with two first signal lines 200, and eight sub-segments 210 of four first signal lines 200 in a same line group 13 are connected to each other by two first connecting lines 310.

In these embodiments, a ratio between the number of the first signal lines 200 and the number of the first connecting lines 310 is 2:1, which can not only avoid the wiring area around the first area HA being oversized if the number of the first connecting lines 310 is too great, but also reduce the uneven display at two sides of the first area HA under low gray-scale images due to drive hysteresis if the number of the first connecting lines 310 is too less.

Optionally, the two first signal lines 200 connected to the pixel circuits 100 in a same row are arranged in different layers, and the first connecting line 310 is arranged in the same layer as one of the first signal lines 200 connected with the first connecting line 310.

In these optional embodiments, the two first signal lines 200 connected to the pixel circuits 100 are arranged in different layers, which can reduce the size of the space occupied by the two first signal lines 200 corresponding to the pixel circuits 100. Moreover, the first connecting line 310 is arranged in the same layer as one of the first signal lines 200 connected with the first connecting line 310, so that the first connecting line 310 can be prepared simultaneously with one of the first signal lines 200, which can not only simplify the preparation process of the array base plate 10, but also improve the connection strength between the first connecting line 310 and the first signal lines 200.

In some optional embodiments, the array base plate 10 further includes a display area and a non-display area NA around at least a portion of the display area, and the display area may be the second area AA as described above. The drive circuit 12 may be located in the non-display area NA, so as to reduce the effect of the drive circuit 12 on the display effect of the display area.

Optionally, if the drive circuit 12 is located at one side of the display area and the first signal line 200 extends from the drive circuit 12 to the other side of the display area, one end of the first signal line 200 is connected with the drive circuit 12 at one side of the display area, and the end of the first signal line 200 away from the drive circuit 12 may be suspended at the other side of the display area.

Optionally, in some other embodiments, referring to FIGS. 1-9, the at least one connecting line 300 includes at least one second connecting line 320, and ends of at least two of the n first signal lines 200 away from the drive circuit 12 are connected by the second connecting line 320.

As shown in FIG. 9, if the first signal line 200 includes two sub-segments 210, for the sub-segment 210 located between the first area HA and the drive circuit 12, one end of the sub-segment 210 is connected to the drive circuit 12, and the other end of the sub-segment 210 is connected to the first connecting line 310; for the sub-segment 210 located at a side of the first area HA away from the drive circuit 12, one end of the sub-segment 210 is connected to the first connecting line 310, and the other end of the sub-segment 210 is connected to the second connecting line 320. That is, the ends of at least two of the n first signal lines 200 away from the drive circuit 12 are connected by the second connecting line 320.

In these embodiments, the other ends of at least two first signal lines 200 away from the drive circuit 12 are connected to each other by the second connecting line 320, which can decrease drive hysteresis, and further reduce the uneven display under low gray-scale images.

As described above, n may be equal to four, a same pixel circuit group 11 includes two rows of the pixel circuits 100, and the line group 13 corresponding to a same pixel circuit group 11 includes four first signal lines 200, i.e., two rows of the pixel circuits 100 correspond to four first signal lines 200, and two first signal lines 200 may be connected to a plurality of pixel circuits 100 in a same row. Therefore, the four first signal lines 200 in a same line group 13 are connected by two second connecting lines 320, for example, two first signal lines 200 connected to the pixel circuits 100 in a same row are connected by a same second connecting line 320. It can be avoided that too many signals from the second connecting line 320 increase the difficulty for preparing the array base plate 10, and further the drive hysteresis of the pixel circuits 100 of in a same row, which causes uneven display of sub-pixels in a same row at two sides of the first area HA, can be reduced.

Optionally, the four first signal lines 200 in a same line group 13 are connected by two second connecting lines 320, the pixel circuits 100 in a same row are connected correspondingly with two first signal lines 200, and the two first signal lines 200 corresponding to the pixel circuits 100 in a same row are connected to a same second connecting line 320. The first signal lines 200 corresponding to the pixel circuits 100 in a same row are usually located close, and a same second connecting line 320 is connected with the pixel circuits 100 in a same row through the first signal lines 200, which can reduce the size of the second connecting line 320.

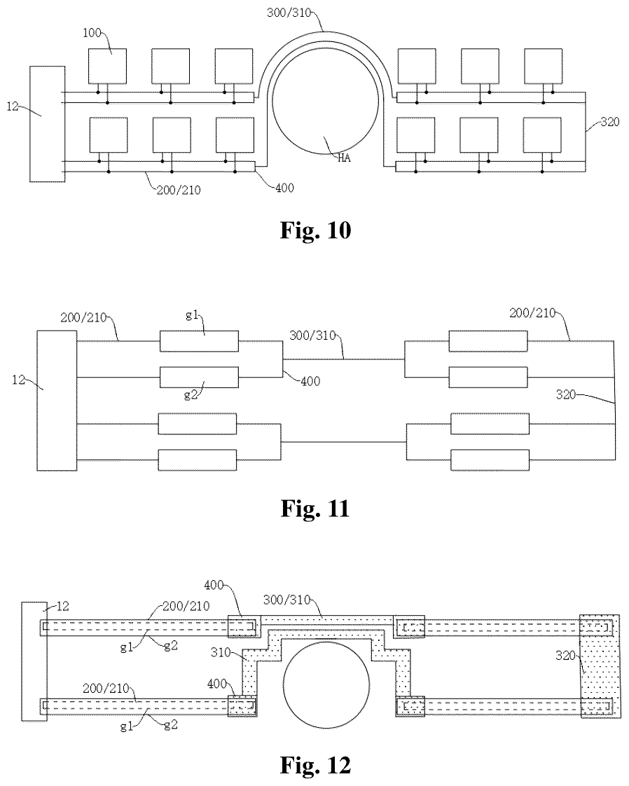

Alternatively, in other embodiments, as shown in FIGS. 10-12, the four first signal lines 200 in a same line group 13 may be connected by one second connecting line 320, which can further reduce the number of the second connecting lines 320 and reduce the difficulty of the preparation process of the array base plate 10.

Position of the film layers of the second connecting line 320 may be arranged in various ways. For example, the array base plate 10 includes a substrate, and the second connecting line 320 may be arranged at a side of the first signal line 200 away from or close to the substrate.

In some optional embodiments, referring to FIGS. 1-14, the array base plate 10 further includes a linking line 400, the connecting line 300 is connected with at least two first signal lines 200 through the linking line 400, and the linking line 400 is connected with the first signal lines 200 through a via.

In these embodiments, at least two first signal lines 200 are connected to each other by the linking line 400 and then connected to the connecting line 300, and thus the original wiring preparation process of the first signal lines 200 may be not changed. The linking line 400 is prepared after the first signal lines 200, and the linking line 400 is connected with the first signal lines 200 through a via, so that a plurality of first signal lines 200 are connected to each other, and the connecting line 300 is only connected to the linking line 400, which can simplify the connection between a plurality of first signal lines 200 and a same connecting line 300.

Optionally, as shown in FIGS. 6, 9, and 12, the linking line 400 and the connecting line 300 may be arranged in a same layer. For example, if the array base plate 10 includes a linking layer in which the linking line 400 is located, the connecting line 300 may also be located in the linking layer. In other embodiments, the linking line 400 and the connecting line 300 may be arranged in different layers.

In any of the above embodiments, if the connecting line 300 includes the first connecting line 310 and the first signal line 200 includes the sub-segment 210, two or more sub-segments 210 located at a same side of the first area HA may be connected to each other by the linking line 400, and the first connecting line 310 only needs to be connected to the linking lines 400 located at two sides of the first area HA. If the connecting line 300 includes the second connecting line 320, the linking line 400 may be directly connected to the ends of two or more first signal lines 200 away from the drive circuit 12, and the second connecting line 320 is connected with the linking line 400, so that the second connecting line 320 can be connected to two or more first signal lines 200.

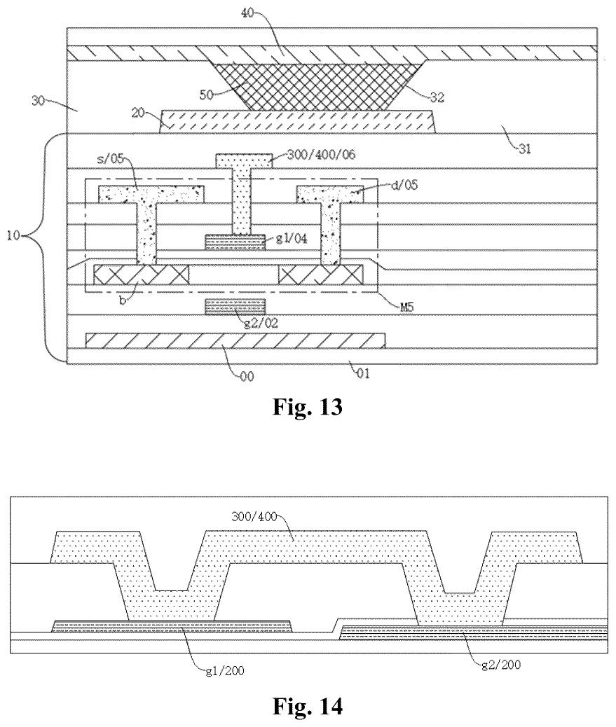

Optionally, as shown in FIGS. 13 and 14, the array base plate 10 includes a substrate 01 and an electrically conductive layer and a linking layer arranged on the substrate 01, the first signal line 200 is located in the electrically conductive layer, the linking line 400 is located in the linking layer, and the linking layer is located a side of the electrically conductive layer away from the substrate.

In these optional embodiments, the linking layer and the linking line 400 located within the linking layer may be prepared after the electrically conductive layer and the first signal line 200 located within the electrically conductive layer.

Optionally, the array base plate 10 may include a substrate 01 and a first electrically conductive layer 02, a second electrically conductive layer, a third electrically conductive layer 04, a fourth electrically conductive layer 05, and a fifth electrically conductive layer 06 stacked at one side of the substrate 01. An insulating layer is arranged between every adjacent pair of electrically conductive layers. As described above, the pixel circuit 100 arranged on the array base plate 10 includes a compensation module 160 with a fifth transistor M5, and the fifth transistor M5 includes a semiconductor portion b, a top gate g1, a bottom gate g2, a source s, and a drain d. As an example, the bottom gate g2 may be located in the first electrically conductive layer 02, the top gate g1 may be located in the third electrically conductive layer 04, and the source s and the drain d may be located in the fourth electrically conductive layer 05. For the two first signal lines 200 connected correspondingly with the two gates of a same compensation transistor M5, one of the first signal lines 200 is arranged in the same layer as the bottom gate g2, and the other of the first signal lines 200 is arranged in the same layer as the top gate g1.

Optionally, the connecting line 300 and/or the linking line 400 may be located in the fourth electrically conductive layer 05. Alternatively, the array base plate 10 further includes the fifth electrically conductive layer 06 located at a side of the fourth electrically conductive layer 05 away from the substrate 01, and the connecting line 300 and/or the linking line 400 may be located in the fifth electrically conductive layer 06.

Optionally, the electrically conductive layer may be any of the first electrically conductive layer 02, the second electrically conductive layer, the third electrically conductive layer 04, and the fourth electrically conductive layer 05 as described above, and the linking layer may be any of the second electrically conductive layer, the third electrically conductive layer 04, the fourth electrically conductive layer 05, and the fifth electrically conductive layer 06, as long as the linking layer is located at a side of the electrically conductive layer away from the substrate 01.

Optionally, the array base plate 10 may further include a metal shading layer 00 located at a side of the semiconductor portion b towards the substrate 01 and for shading light, so as to prevent the light from being incident on the semiconductor portion b and affecting its performance.

Optionally, as described above, the first signal line 200 may be connected to the gate of the compensation module, and thus the first signal line 200 may be arranged in the same layer as the gate to which it is connected, so that a portion of the first signal line 200 may be reused as the gate to further simplify the preparation of the array base plate 10.

In some other embodiments, the first signal line 200 may be the fourth scan line and configured to be connected to the gate of the sixth transistor M6 of the third initialization module 190. The sixth transistor M6 includes a top gate and a bottom gate which may be each connected with a first signal line 200 (i.e., the fourth scan line).

The embodiments of the second aspect of the present application further provide a display panel including the array base plate 10 of any of the above embodiments. Optionally, as shown in FIG. 13, the display panel may further include a pixel electrode layer 20, a pixel defining layer 30, and a common electrode layer 40, the pixel defining layer 30 includes a pixel defining portion 31 and a pixel opening 32 within which a light-emitting unit 50 is arranged, and the common electrode 40 is located at a side of the pixel defining layer 30 and the light-emitting unit 50 away from the array base plate 10.

The embodiments of the third aspect of the present application further provide a display module including the display panel or the array base plate 10 as described above. Herein, the display module may further include a polarizer, a touch control layer, a cover plate, and other structures. The polarizer is arranged between the touch control layer and the display panel, and the cover plate is arranged at a side of the touch control layer away from the display panel.

The embodiments of the fourth aspect of the present application further provide a display apparatus including the display panel or the display module of any of the above embodiments. The display apparatus in the embodiments of the present application includes, but is not limited to, a cellular phone, a Personal Digital Assistant (PDA), a Virtual Reality (VR) display apparatus, a tablet computer, an e-book, a TV, a door access control, a smart landline phone, a console, and other devices with display function.

Although the present application has been described with reference to the preferred embodiments, various improvements can be made, and parts thereof can be replaced with equivalents without departing from the scope of the present application. In particular, as long as there is no structural conflict, the technical features described in the various embodiments can be combined in any manner. The present application is not limited to the particular embodiments disclosed herein, but includes all technical solutions falling within the scope of the claims.

What is claimed is:

1. An array base plate, comprising:
a plurality of pixel circuit groups each comprising a plurality of pixel circuits, the pixel circuits of the plurality of pixel circuit groups being distributed in an array;
a drive circuit;
a plurality of line groups, the drive circuit being connected with the pixel circuit groups through the line groups, each of the line groups comprising n first signal lines, the n first signal lines in the line group being configured to transmit a synchronization signal, and n being a positive integer greater than one; and
at least one connecting line configured to connect at least two first signal lines in a same line group.

2. The array base plate according to claim 1, wherein the plurality of line groups comprise at least a first line group, and each first signal line in the first line group comprises two sub-segments spaced apart; and
the at least one connecting line comprises at least one first connecting line, the first connecting line connects the sub-segments of n first signal lines in a same first line group, and a number of first connecting lines corresponding to the first line group is greater than 1 and less than or equal to (n-1).

3. The array base plate according to claim 2, wherein the array base plate comprises at least a first area, the two sub-segments of a same first signal line are arranged at two sides of the first area, respectively, the first connecting line is around at least a portion of the first area, and at least one first connecting line connects the sub-segments of at least two first signal lines in a same first line group.

4. The array base plate according to claim 2, wherein the at least one first connecting line comprises a plurality of first connecting lines, at least two of the plurality of first connecting lines are arranged in different layers or the plurality of first connecting lines are arranged in a same layer; and
the array base plate comprises a substrate, and the first connecting line is located at a side of the first signal line away from or close to the substrate.

5. The array base plate according to claim 3, wherein n is equal to four, the pixel circuit group comprises two rows of the pixel circuits, the pixel circuits in a same row are connected correspondingly with two first signal lines, and eight sub-segments of four first signal lines in a same line group are connected by two first connecting lines.

6. The array base plate according to claim 5, wherein the two first signal lines connected to the pixel circuits in a same row are arranged in different layers, and the first connecting line is arranged in the same layer as one of the first signal lines connected with the first connecting line.

7. The array base plate according to claim 5, wherein the first connecting line is connected to four sub-segments of two first signal lines corresponding to the pixel circuits in a same row.

8. The array base plate according to claim 1, wherein the array base plate comprises a display area and a non-display area arranged around at least a portion of the display area, the drive circuit is located in the non-display area, the at least one connecting line comprises at least one second connecting line, and ends of at least two of the n first signal lines away from the drive circuit are connected by the second connecting line.

9. The array base plate according to claim 8, wherein the pixel circuit group comprises two rows of the pixel circuits, the line group comprises four first signal lines, and the four first signal lines in a same line group are connected by one second connecting line; or
the four first signal lines in a same line group are connected by two second connecting lines.

10. The array base plate according to claim 8, wherein the four first signal lines in a same line group are connected by two second connecting lines, the pixel circuits in a same row are connected correspondingly with two first signal lines, and the two first signal lines corresponding to the pixel circuits in a same row are connected to a same second connecting line; and
the array base plate comprises a substrate, and the second connecting line is located at a side of the first signal line away from or close to the substrate.

11. The array base plate according to claim 1, wherein the array base plate further comprises a linking line, the connecting line is connected with at least two first signal lines through the linking line, and the linking line is connected with the first signal lines through a via.

12. The array base plate according to claim 11, wherein the array base plate comprises a substrate and an electrically conductive layer and a linking layer arranged on the substrate, the first signal line is located in the electrically conductive layer, the linking line is located in the linking layer, and the linking layer is located a side of the electrically conductive layer away from the substrate; and
the connecting line is located in the linking layer.

13. The array base plate according to claim 1, wherein the pixel circuit group comprises at least one row of the pixel circuits or at least one column of the pixel circuits.

14. The array base plate according to claim 1, wherein the pixel circuit group comprises two rows of the pixel circuits, n is equal to four, and each row of the pixel circuits are connected correspondingly with two first signal lines.

15. The array base plate according to claim 1, wherein the pixel circuit group comprises two adjacent rows of the pixel circuits.

16. The array base plate according to claim 13, wherein the pixel circuit comprises a plurality of functional modules, and the two first signal lines connected to the pixel circuits in a same row are connected to different functional modules; or at least one of the plurality of functional modules comprises two control terminals, and the two first signal lines connected to the pixel circuits in a same row are connected with the two control terminals of a same functional module.

17. The array base plate according to claim 16, wherein the functional modules comprise a compensation module, the compensation module comprises a compensation transistor with two gates, and the two gates form the two control terminals;
the two gates are a top gate and a bottom gate, respectively.

18. The array base plate according to claim 17, wherein the compensation transistor is an oxide transistor.

19. A display module comprising the array base plate according to claim 1.

20. A display apparatus comprising the display module according to claim 19.
